(19) United States
(12) Patent Application Publication
(10) Pub. No.: US 2011/0278205 A1
(43) Pub. Date: Nov. 17, 2011

(54) METHOD AND APPARATUS OF CONVEYING OBJECTS TO BE PROCESSED AND COMPUTER-READABLE STORAGE MEDIUM STORING PROGRAM

(75) Inventor: Masaki ENDO, Oshu-shi (JP)

(73) Assignee: TOKYO ELECTRON LIMITED, Tokyo (JP)

(21) Appl. No.: 13/094,448

(22) Filed: Apr. 26, 2011

(30) Foreign Application Priority Data
May 11, 2010 (JP) 2010-109712

(51) Int. Cl. H01L 21/677; B07C 5/34; B07C 5/00

(52) U.S. Cl. 209/555; 209/552

(57) ABSTRACT

A method and an apparatus of simply and rapidly conveying objects having no detected abnormalities, and a computer-readable storage medium storing a program for use in the conveying method and apparatus. When abnormalities on semiconductor wafers in a wafer boat are detected, abnormality positions and types of abnormalities are identified and skip positions are determined (Step S4). A withdrawal process on the wafers at the skip positions is skipped whereas an automatic withdrawal process on the wafers having no detected abnormalities is performed (Step S5). Continuously, when some of the wafers remain in the wafer boat (Yes at Step S6) and automatic withdrawable wafers exist (Yes at Step S7), an automatic withdrawal process on the automatic withdrawable wafers is performed (Step S8). Thereafter, a manual withdrawal process on the remaining wafers is performed (Step S10).

### CROSS-REFERENCE TO RELATED APPLICATIONS

This application is based upon and claims the benefit of priority from Japanese Patent Application No. 2010-109712, filed on May 11, 2010, the entire contents of which are incorporated herein by reference.

### TECHNICAL FIELD

Embodiments described herein relate generally to a method and an apparatus of conveying objects to be processed and a computer-readable storage medium storing a program for use in the conveying method and apparatus.

### BACKGROUND

In manufacturing semiconductor devices, a processing apparatus for performing a film forming process on an object to be processed, e.g., a semiconductor wafer, is used. Such processing apparatus may include a plurality of sensors. For example, in a batch-type processing apparatus, sensors may be disposed in a wafer boat to detect whether semiconductor wafers are exactly accommodated at predetermined positions in the wafer boat. Also, with data acquired through such sensors, techniques for performing high-level maintenance on a processing apparatus have been proposed in variety of ways.

For example, a substrate processing apparatus has been proposed for preventing a substrate from being damaged due to interference occurring between a support member of a conveying unit and the substrate by determining whether the support member is ready to perform a conveying operation (for example, See Japanese Laid-Open Patent Publication No. 2009-152396).

With this substrate processing apparatus, however, when detecting abnormalities on some semiconductor wafers accommodated in a wafer boat, the remaining semiconductor wafers having no detected abnormalities are manually removed (withdrawn) from the wafer boat that currently accommodates all semiconductor wafers. Such manual withdrawal process for semiconductor wafers having no detected abnormalities is troublesome and time consuming. Moreover, it may be difficult to take out the semiconductor wafers having no detected abnormalities without delay.

### SUMMARY

It is, therefore, an aim of some embodiments disclosed in the present disclosure to provide a method and an apparatus of simply and rapidly remove objects having no detected abnormalities to be processed. The method may also be embodied in a computer-readable storage medium storing a program for use in the conveying method and apparatus.

According to one aspect of the present disclosure, there is provided a method of conveying objects to be processed, the method comprising: determining whether abnormalities on the objects accommodated in a processing apparatus are detected based on data from sensors disposed on the processing apparatus; identifying accommodation positions of the objects determined to have the detected abnormalities, and identifying types of detected abnormalities; deciding skip positions based on the identified accommodation positions and the identified types of the detected abnormalities; and skipping a conveyance of the objects accommodated at the decided skip positions and performing an automatic conveyance on the objects having no detected abnormalities.

After performing the automatic conveyance, in some embodiments, the object conveying method may further include identifying conveyable objects among the determined objects having the occurred abnormalities; and performing the automatic conveyance on the identified conveyable objects.

Identifying conveyable objects, in some embodiments, may be performed based on the types of abnormalities that occurred for the determined objects having the occurred abnormalities.

In addition, identifying conveyable objects, in other embodiments, may further include displaying the decided skip positions; receiving data related to an alteration in the decided skip positions being displayed; and identifying other objects to be conveyed among the determined objects based on the received data related to the alternation in the decided skip positions.

After performing the automatic conveyance, in some embodiments, the object conveying method may further include performing a manual conveyance of the objects remaining in the processing apparatus.

According to the second aspect of the present disclosure, an apparatus of conveying objects to be processed includes: an abnormality determination unit configured to determine whether abnormalities on the objects accommodated in a processing apparatus are detected based on data from sensors disposed on the processing apparatus; an abnormality identification unit configured to identify accommodation positions of the objects determined to have the detected abnormalities, and types of the detected abnormalities; a skip position decision unit configured to decide skip positions based on the identified accommodation positions and the identified types of the detected abnormalities; and a conveying unit configured to skip a conveyance of the objects accommodated at the decided skip positions and configured to perform an automatic conveyance of the objects having no detected abnormalities.

According to a third aspect of the present disclosure, there is provided a computer-readable storage medium storing instructions that, when executed by a computer, cause the computer to perform the operations of: determining whether abnormalities on the objects accommodated in a processing apparatus are detected based on data from sensors disposed on the processing apparatus; identifying accommodation positions of the objects determined to have the detected abnormalities, and types of the detected abnormalities; deciding skip positions based on the identified accommodation positions and the identified types of the detected abnormalities; and skipping a conveyance of the objects accommodated at the decided skip positions and performing an automatic conveyance on the objects having no detected abnormalities.

Therefore, in accordance with the present disclosure, it is possible to simply and rapidly convey objects to be processed, the objects having no detected abnormalities.

### BRIEF DESCRIPTION OF THE DRAWINGS

FIG. 1 is a diagram showing a configuration of a processing apparatus in accordance with one embodiment of the present disclosure.

FIG. 2 is a block diagram showing a configuration example of a control unit shown in FIG. 1.

FIG. 3 is a diagram showing an example of an abnormality data storage unit.

FIG. 4 is a flowchart explaining a withdrawal process for objects to be processed in accordance with one embodiment of the present disclosure.

FIGS. 5A through 5C are diagrams explaining the withdrawal process for the objects to be processed in accordance with one embodiment of the present disclosure.

FIG. 6 is a flowchart explaining a withdrawal process for objects to be processed in accordance with another embodiment of the present disclosure.

FIGS. 7A through 7C are diagrams showing examples of displaying abnormality data.

FIGS. 8A and 8B are diagrams explaining the withdrawal process for the objects to be processed in accordance with another embodiment of the present disclosure.

### DETAILED DESCRIPTION

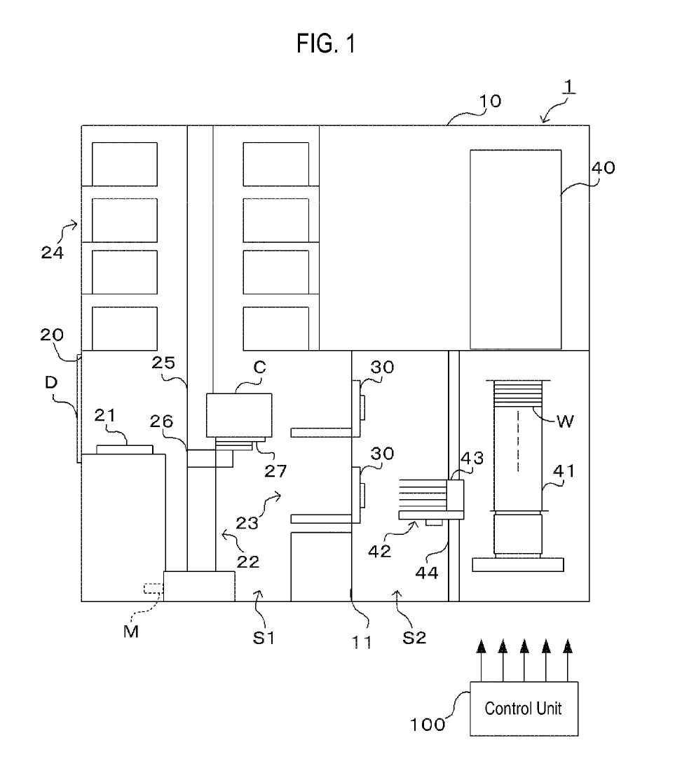

Embodiments of a method and an apparatus of conveying objects to be processed and a computer-readable storage medium storing a program for use in the conveying method and apparatus will now be described in detail with reference to a processing apparatus shown in FIG. 1 upon withdrawing semiconductor wafers that are accommodated in a wafer boat of a batch-type heat treatment furnace in the processing apparatus.

As shown in FIG. 1, a process chamber 10 of a processing apparatus 1 according to one embodiment of the present disclosure is divided by a partition wall 11 into an operation area 51 and a loading area S2. The operation area 51 is configured as an area for conveying and retaining a carrier C, which is a closed-type transfer vessel accommodating a plurality of semiconductor wafers W, e.g., 25 sheets of semiconductor wafers, and maintained under an atmosphere of air. Meanwhile, the loading area S2 is configured as an area for performing heat treatment, e.g., a film forming treatment or an oxidation treatment, on semiconductor wafers W, and maintained under an inert gas atmosphere, e.g., a nitrogen gas atmosphere.

In the operation area S1, a load port 21, a carrier conveyor 22, a transfer stage 23, and retaining portions 24 are disposed.

The load port 21 is configured to mount thereon the carrier C which is carried-in through an external transfer mechanism (not shown) from a transfer port 20 being disposed at a lateral position of the process chamber 10. At an external position of the process chamber 10 corresponding to the transfer port 20, for example, a door D is disposed to make the transfer port 20 have an openable and closable configuration.

The carrier conveyor 22 is disposed between the load port 21 and the transfer stage 23 to convey the carrier C in the operation area S1. The carrier conveyor 22 is provided with a support column 25 and a horizontal arm 26 being disposed at a lateral side of the support column 25. The support column 25 is vertically elongated to be disposed in the process chamber 10. The horizontal arm 26 is configured to be movable upward and downward by a motor M which is disposed at a lower side of the support column 25. For example, an encoder is combined into the motor M such that a vertical position of the horizontal arm 26 is detected in terms of an encoder value outputted from the encoder. Also, a transfer arm 27 made of, e.g., a multi-joint arm, is disposed on the horizontal arm 26 to be moved upward and downward as the horizontal arm 26 moves upward and downward. The transfer arm 27 is configured to be movable in a horizontal direction through a motor (not shown). In this way, the horizontal arm 26 is configured to move the transfer arm 27 in upward, downward, and horizontal directions, thereby transferring the carrier C.

The transfer stage 23 is disposed on the partition wall 11 facing the operation area S1 to mount thereon the carrier C that is transferred through the carrier conveyor 22. The transfer stage 23 may be disposed at upper and lower positions on the partition wall 11, for example. On the transfer stage 23, the semiconductor wafers W are taken out from the carrier C, which is mounted on the transfer stage 23, to be discharged to the loading area S2 by a movable loading mechanism 42 which will be described later. Also, a portion of the partition wall 11 corresponding to a lateral position of the transfer stage 23 is opened. A shutter 30 is disposed on the partition wall 11 facing the loading area S2 so as to block the opened portion of the partition wall 11. The retaining portions 24 are disposed at an upper side in the operation area S1 to retain the carrier C. For example, the retaining portions 24 may be disposed in a set of four columns and two rows such that the support column 25 (in a conveying area of the carrier C) may be inserted into the set of the retaining portions 24.

A heat treatment furnace 40 serving as a bell-type processing unit is disposed in the loading area S2. The lower portion of the heat treatment furnace 40 is open and functions as a furnace opening. At a lower side of the heat treatment furnace 40, a wafer boat 41 serving as a holding support mechanism for holding and supporting plural sheets of the semiconductor wafers W is disposed to be movable upward and downward through an elevation mechanism (not shown). Wafer position sensors, e.g., a pair of photo sensors, are disposed on the wafer boat 41 so as to detect whether the semiconductor wafers W are accommodated in the wafer boat 41, or to detect accommodation positions of the semiconductor wafers W in the wafer boat 41.

The movable loading mechanism 42 is disposed between the wafer boat 41 and the partition wall 11. The movable loading mechanism 42 is configured to transfer the semiconductor wafers W between the carrier C mounted on the transfer stage 23 and the wafer boat 41. Also, an arm 43 capable of moving and mounting plural sheets of the semiconductor wafers W, e.g., in batches is disposed on the movable loading mechanism 42 to be movable in forward and backward directions. The movable loading mechanism 42 is configured to be rotatable centering on an elevation shaft 44 through a motor (not shown), and configured to be movable upward and downward along the elevation shaft 44.

Various types of sensors are disposed in the process chamber 10 of the processing apparatus 1. For example, in the heat treatment furnace 40, temperature sensors for measuring temperature in the heat treatment furnace 40 and pressure sensors for measuring pressure therein may be disposed. Also, on various motors and cylinders, position sensors such as end-limit sensors, base position sensors, and the like are disposed so as to detect positions of the motors and the cylinders.

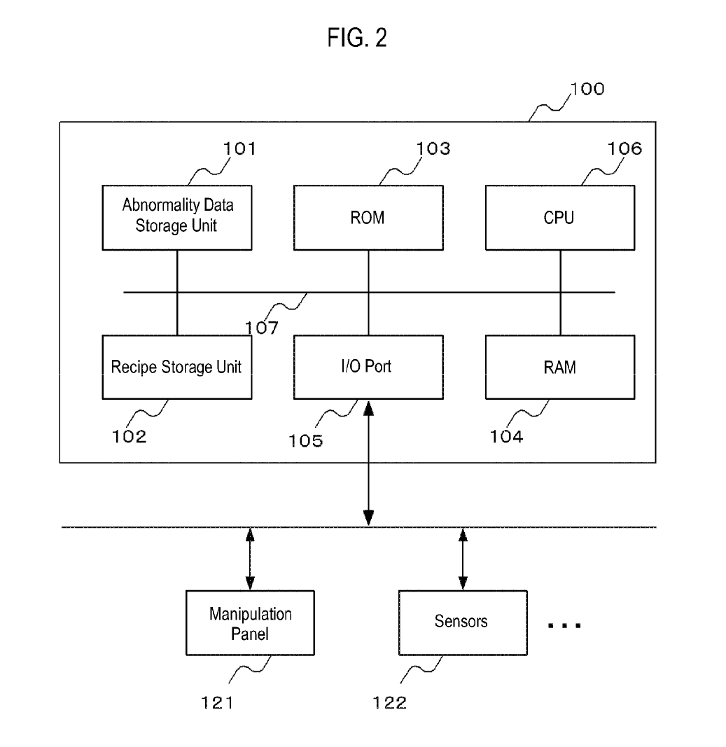

Further, the processing apparatus 1 is connected to a control unit 100 that controls the components of the processing apparatus 1. FIG. 2 shows a configuration of the control unit 100. As shown in FIG. 2, the control unit 100 is connected to a manipulation panel 121 and sensors 122 such as photo sensors and the like. The control unit 100 is configured to output control signals to, e.g., the movable loading mechanism 42, the horizontal arm 26, and the like based on data from the sensors 122 such as the photo sensors and the like.

The manipulation panel 121 is provided with a display section (display screen) and manipulation buttons. The manipulation panel 121 is configured to send manipulation commands of an operator to the control unit 100 and configured to display data from the control unit 100 on the display screen.

The sensors 122, such as the photo sensors, detect positions and the like in association with the semiconductor wafers W to inform the control unit 100 of the detected data (such as the positions and the like).

As shown in FIG. 2, the control unit 100 is provided with an abnormality data storage unit 101, a recipe storage unit 102, a ROM (Read Only Memory) 103, a RAM (Random Access Memory) 104, an I/O (Input/Output) port 105, a CPU (Central Processing Unit) 106, and a bus 107 for connecting them to each other.

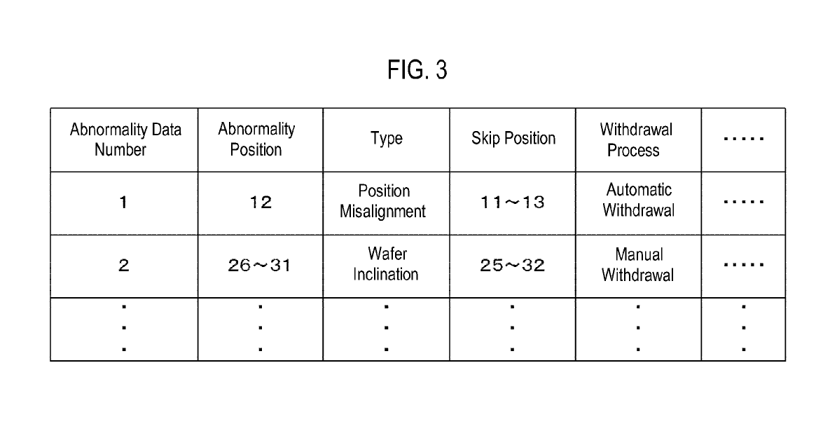

The abnormality data storage unit 101 is configured to store data in association with abnormalities on the semiconductor wafers W. As shown in FIG. 3, the abnormality data storage unit 101 may store data related to, for example, an abnormality data number, an abnormality position, a type of abnormality data, skip positions, a withdrawal process, and the like. Herein, the abnormality position is referred to as a position at which an abnormality-detected semiconductor wafer W is accommodated in the wafer boat 41. In some embodiments, the type of abnormality data may include a wafer position misalignment, a double wafer, a wafer inclination, and the like. The skip positions are referred to as positions at which a withdrawal process of semiconductor wafers W are left out (skipped) when automatically performing a withdrawal process on semiconductor wafers W having no detected abnormalities. In the present embodiment, regardless of the type of abnormality data, the skip positions are determined to be in the range of ±1 of the abnormality-detected positions. The withdrawal process is referred to as a process of withdrawing semiconductor wafers W for which an abnormality is not detected. The withdrawal process includes an automatic withdrawal process for automatically withdrawing the semiconductor wafers W through the movable loading mechanism 42, and a manual withdrawal process for manually withdrawing the semiconductor wafers W through a manual manipulation of the movable loading mechanism 42 by an operator.

The recipe storage unit 102 is configured to store a process recipe for arranging control sequences according to types of processes being executed or to be executed in the processing apparatus 1. The process recipe is a recipe being prepared for each of the treatments (processes) that are actually performed by the operator. This process recipe contains specific operation programs for the respective components of the processing apparatus 1.

The ROM 103 is configured with an EEPROM (Electrically Erasable Programmable Read Only memory), a flash memory, a hard disk, or the like. The ROM 103 is configured to serve as a storage medium storing an operation program and the like of the CPU 106.

The RAM 104 is configured to serve as an operation area and the like of the CPU 106.

The I/O port 105, for example, is configured to supply data from the sensors 122 to the CPU 106 and configured to send control signals outputted from the CPU 106 to the respective components of the processing apparatus 1.

The CPU 106 is configured as the center of the control unit 100 to execute the operation program stored in the ROM 103. Also, in response to commands inputted from the manipulation panel 121, the CPU 106 controls operations of the processing apparatus 1 according to the process recipe stored in the recipe storage unit 102.

The bus 107 is configured to relay data among the respective components of the processing apparatus 1.

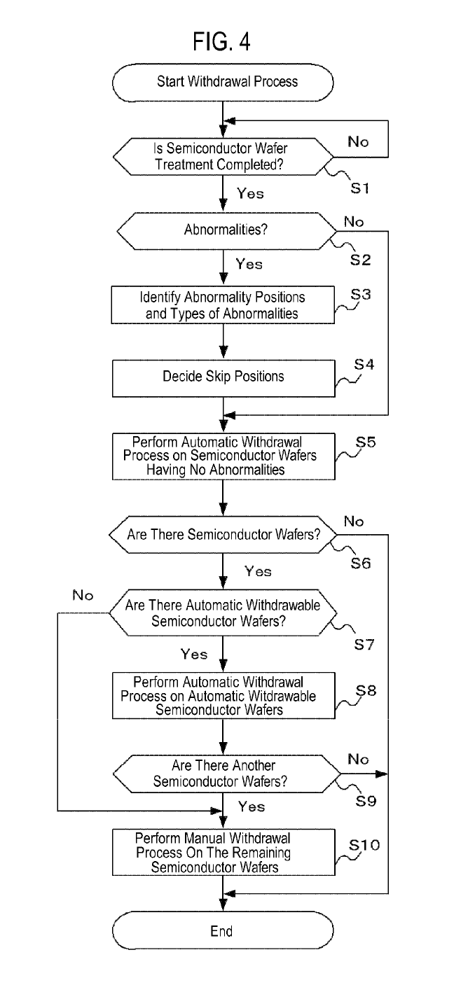

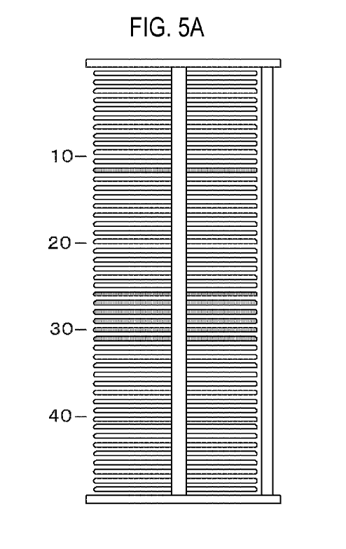

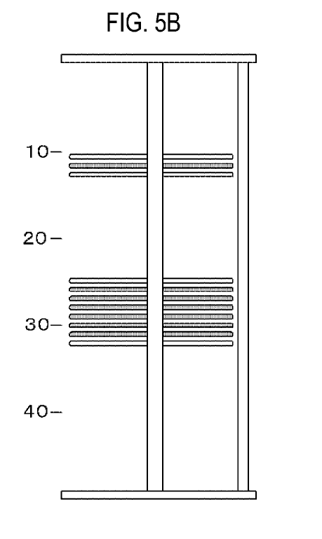

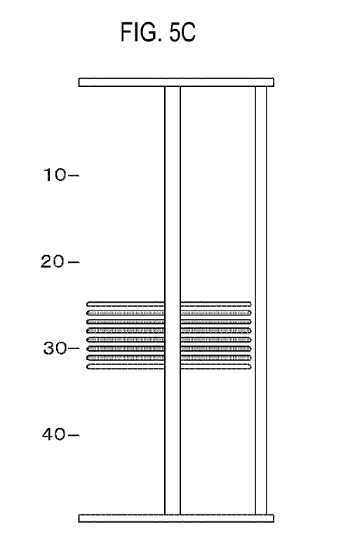

Hereinafter, a conveying method (withdrawal process) for objects to be processed will be described. In the conveying method for objects to be processed in accordance with the present disclosure, it is initially determined whether abnormalities on semiconductor wafers W accommodated in the wafer boat 41 are detected before conveying (withdrawing) the semiconductor wafers W from the wafer boat 41. Subsequently, if it is determined that abnormalities are detected, a withdrawal process for the abnormality-detected semiconductor wafers W is skipped whereas an automatic withdrawal process for the semiconductor wafers W having no detected abnormalities is performed. FIG. 4 is a flowchart explaining the withdrawal process. Also, FIGS. 5A through 5C are diagrams explaining the withdrawal process to show statuses of the semiconductor wafers W being accommodated in the wafer boat 41.

Initially, the control unit 100 (CPU 106) determines whether a treatment for the semiconductor wafers W accommodated in the wafer boat 41 is completed (Step S1 of FIG. 4). If it is determined that the treatment for the semiconductor wafers W is completed (Yes at Step S1), the control unit 100 further determines whether abnormalities on the semiconductor wafers W in the wafer boat 41 are detected (Step S2). Specifically, the CPU 106 identifies the locations of the semiconductor wafers W or the positions thereof based on data from the pairs of photo sensors disposed in the wafer boat 41, and then determines whether abnormalities on the semiconductor wafers W in the wafer boat 41 are detected. If it is determined that no abnormalities on the semiconductor wafers W are detected (No at Step S2), the CPU 106 proceeds to Step S5.

Otherwise, if it is determined that abnormalities on the semiconductor wafers W are detected (Yes at Step S2), the CPU 106 identifies types of abnormalities and positions (abnormality positions) in the wafer boat 41 with respect to the abnormality-detected semiconductor wafers W (Step S3). The CPU 106 then decides skip positions where no withdrawal process is performed on some of the semiconductor wafers W when performing an automatic withdrawal process on the semiconductor wafers W having no detected abnormalities (Step S4). In this way, automatic withdrawal positions for the semiconductor wafers W having no detected abnormalities are determined. Afterwards, the CPU 106 controls the movable loading mechanism 42 to skip the withdrawal process on the semiconductor wafers W accommodated at the skip positions and to perform the automatic withdrawal process on the semiconductor wafers W having no detected abnormalities (Step S5).

For example, as shown in FIG. 5A, upon detecting a position misalignment on a semiconductor wafer W at a 12^{th} position in the wafer boat 41 and wafer inclinations on semiconductor wafers W at 26^{th} to 31^{st} positions in the wafer boat 41, skip positions where no withdrawal process is performed are determined as 11^{th} to 13^{th} positions and 25^{th} to 32^{nd} positions when performing the automatic withdrawal process on the semiconductor wafers W having no detected abnormalities. Thereafter, the CPU 106 controls the movable loading mechanism 42 to skip the withdrawal process on the semiconductor wafers W accommodated at the skip positions, i.e., 11^{th} to 13^{th} and 25^{th} to 32^{nd} positions, and then to perform the automatic withdrawal process on the semiconductor wafers W having no detected abnormalities, as shown in FIG. 5B.

Continuously, the CPU 106 determines whether some of the semiconductor wafers W remain in the wafer boat 41 (Step S6). If it is determined that there are no semiconductor wafers W remaining in the wafer boat 41 (No at Step S6), the CPU 106 terminates this process.

Otherwise, if it is determined that some of the semiconductor wafers W remain in the wafer boat 41 (Yes at Step S6), the CPU 106 further determines whether there are automatic withdrawable semiconductor wafers W among the remaining semiconductor wafers W (Step S7). If it is determined that there are no automatic withdrawable semiconductor wafers W (No at Step S7), the CPU 106 proceeds to Step S10.

On the contrary, if it is determined that there are automatic withdrawable semiconductor wafers W (Yes at Step S7), the CPU 106 performs the automatic withdrawal process on these semiconductor wafers W (Step S8). For example, as shown in FIG. 3, the type of abnormality on the semiconductor wafer W at the 12^{th} position in the wafer boat 41 is determined as the position misalignment, such that the semiconductor wafer W at the 12^{th} position can be automatically withdrawn. Therefore, as shown in FIG. 5C, the CPU 106 performs the automatic withdrawal process on the semiconductor wafers W accommodated at the 11^{th} to 13^{th} positions corresponding to the skip positions where the automatic withdrawal process can be performed.

Subsequently, the CPU 106 determines whether another semiconductor wafer W still remains in the wafer boat 41 (Step S9). If it is determined that there are no semiconductor wafers W remaining in the wafer boat 41 (No at Step S9), the CPU 106 terminates this process.

Otherwise, if it is determined that there are still semiconductor wafers W remaining in the wafer boat 41 (Yes at Step S9), the CPU 106 allows the operator to perform the manual withdrawal process on the remaining semiconductor wafers W (Step S10) and terminates this process.

As described above, in accordance with the present embodiment, the automatic withdrawal process is skipped on the semiconductor wafers W accommodated at the skip positions and performed on the semiconductor wafers W having no detected abnormalities. Therefore, the semiconductor wafers W having no detected abnormalities can be conveyed in a simple and rapid manner.

Further, in accordance with the present embodiment, the automatic withdrawal process can be performed on some automatic withdrawable semiconductor wafers W among the abnormality-detected semiconductor wafers W. Therefore, the withdrawal process on the semiconductor wafers W may be realized in a simple manner.

While one embodiment has been described, various variations and modifications may be made without being limited to the foregoing embodiment. Hereinafter, another embodiment to which the present invention is applicable will be described.

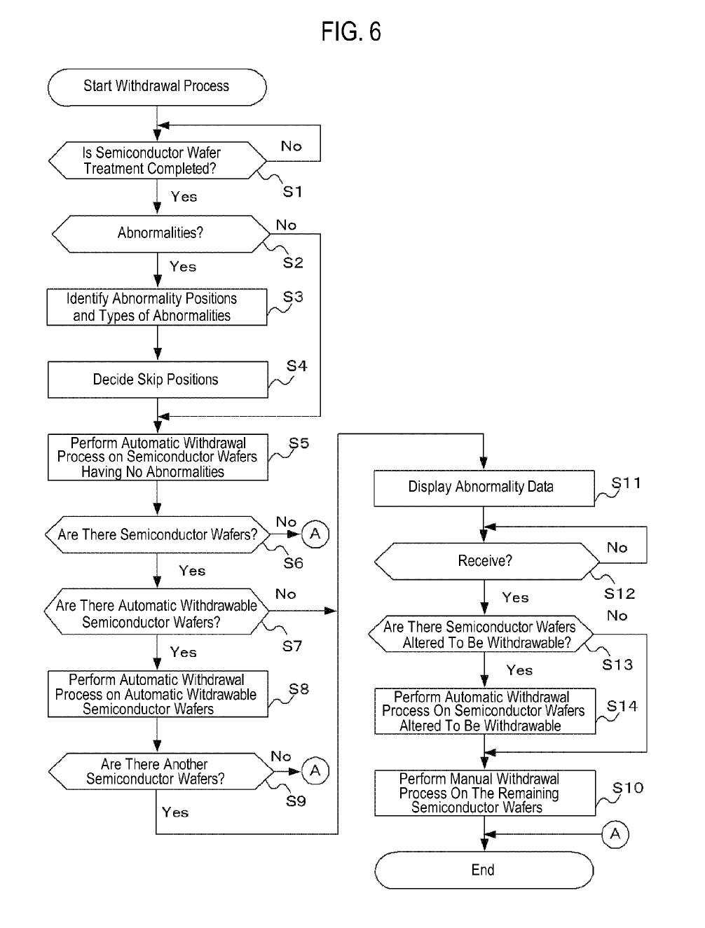

In the aforementioned embodiment, the automatic withdrawal process is determined depending on the types of abnormalities on the abnormality-detected semiconductor wafers W, but it can be modified to perform the automatic withdrawal process on some of the abnormality-detected semiconductor wafers W, which are determined to be automatic withdrawable through, e.g., the eyes of the operator. FIG. 6 is a flowchart explaining a modified withdrawal process in accordance with another embodiment of the present disclosure.

Initially, similar to the aforementioned embodiment, the CPU 106 performs Steps S1 to S9 shown in FIG. 6. Specifically, the CPU 106 determines whether a treatment for semiconductor wafers W accommodated in the wafer boat 41 is completed (Step S1). If it is determined that the treatment for the semiconductor wafers W is completed (Yes at Step S1), the CPU 106 further determines whether abnormalities on the semiconductor wafers W accommodated in the wafer boat 41 are detected (Step S2). Thereafter, if it is determined that abnormalities on the semiconductor wafers W are detected (Yes at Step S2), the CPU 106 identifies abnormality positions and types of abnormalities (Step S3) to decide skip positions (Step S4). And then, the CPU 106 controls the movable loading mechanism 42 to skip a withdrawal process on the semiconductor wafers W accommodated at the skip positions and to perform an automatic withdrawal of the semiconductor wafers W having no detected abnormalities (Step S5). Subsequently, the CPU 106 determines whether some of the semiconductor wafers W remain in the wafer boat 41 (Step S6). If it is determined that some of the semiconductor wafers W remain in the wafer boat 41 (Yes at Step S6), the CPU 106 further determines whether automatic withdrawable semiconductor wafers exist among the remaining wafers (Step S7). If it is determined that automatic withdrawable semiconductor wafers exist (Yes at Step S7), the CPU 106 performs the automatic withdrawal process on the automatic withdrawable semiconductor wafers (Step S8). Continuously, the CPU 106 determines whether some of the semiconductor wafers W still remain in the wafer boat 41 (Step S9).

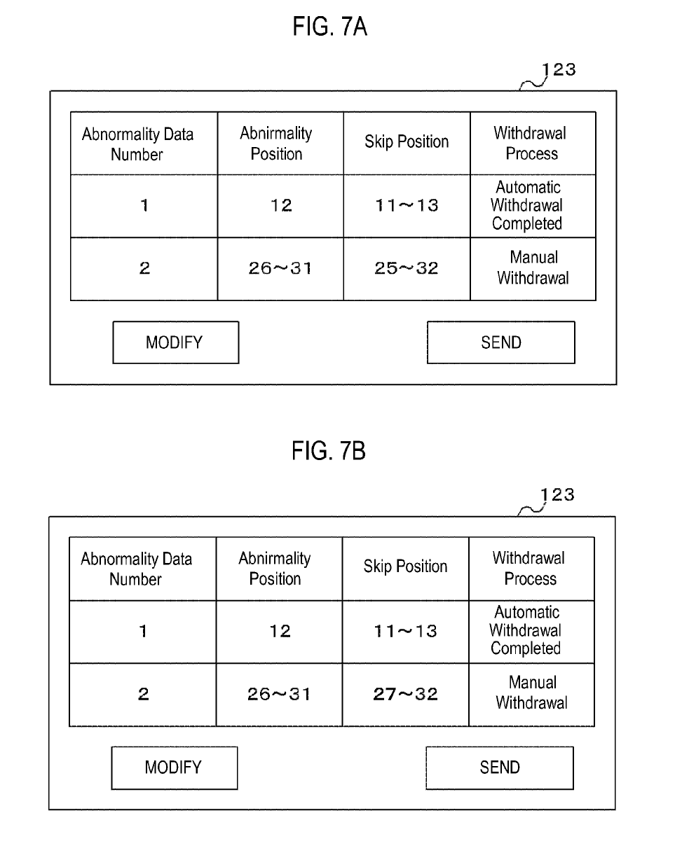

If it is determined that some of the semiconductor wafers W further remain in the wafer boat 41 (Yes at Step S9), the CPU 106 displays abnormality data in association with these remaining semiconductor wafers W on the display (display screen) of the manipulation panel 121, as shown in FIG. 7A (Step S11).

If the operator of the processing apparatus 1 determines, through the eyes of himself or herself, that automatic withdrawable semiconductor wafers W further exist, he or she presses a MODIFY button to alter the 25^{th} to 32^{nd} skip positions to, e.g., 27^{th} to 32^{nd} skip positions as shown in FIG. 7B. And then, the operator of the processing apparatus 1 presses a SEND button to send the modified abnormality data containing the altered skip positions to the CPU 106. In this way, as shown in FIG. 7C, the withdrawal process with respect to the 25^{th} and 26^{th} skip positions is changed into an automatic withdrawal process whereas the withdrawal process with respect to the 27^{th} to 32^{nd} skip positions is changed into a manual withdrawal process. Otherwise, if the operator of the processing apparatus 1 determines, through the eyes of himself or herself, that there are no automatic withdrawable semiconductor wafers W further exist, he or she presses the SEND button without modifying a corresponding abnormality data to send the same to the CPU 106.

Thereafter, the CPU 106 determines whether abnormality data are further received (Step S12). If it is determined that abnormality data are further received (Yes at Step S12), the CPU 106 further determines whether there are semiconductor wafers W altered to be withdrawable (Step S13). If it is determined that there are no semiconductor wafer W altered to be withdrawable (No at Step S13), the CPU 106 proceeds to Step S10.

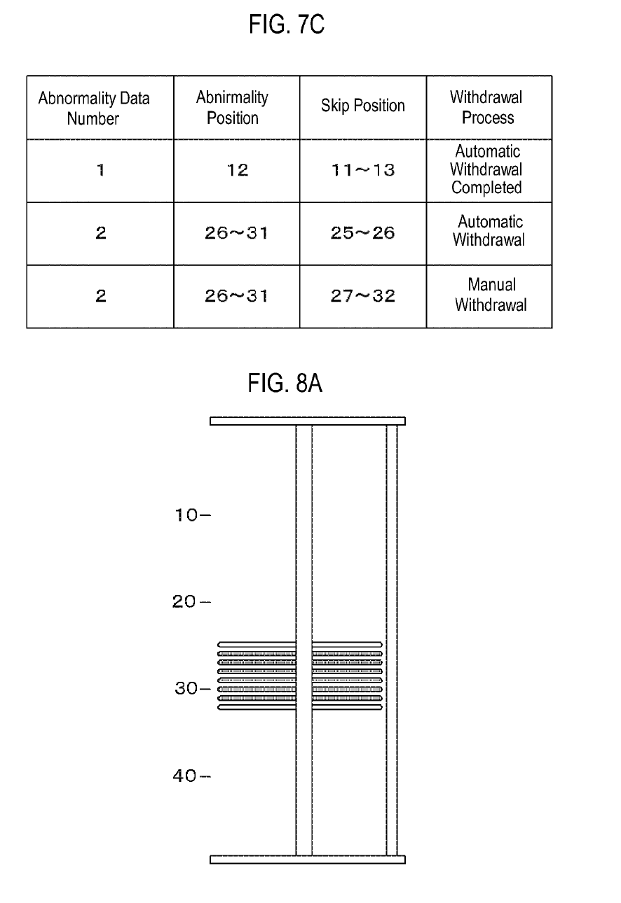

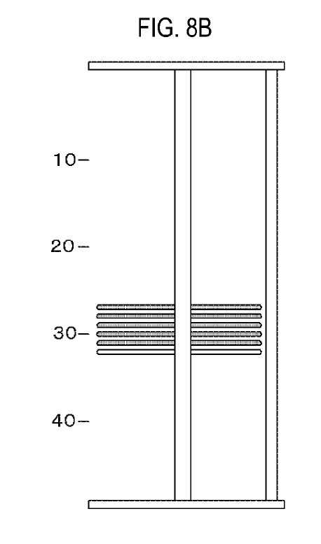

Otherwise, if it is determined that there are semiconductor wafers W altered to be withdrawable (Yes at Step S13), the CPU 106 controls the movable loading mechanism 42 to perform the automatic withdrawal process on the semiconductor wafers W altered to be withdrawable (Step S14). For instance, when the semiconductor wafers W remain at the 25^{th} to 32^{nd} positions, shown in FIG. 8A, in the wafer boat 41, the CPU 106 performs the automatic withdrawal process only on the semiconductor wafers W at the automatic withdrawable positions, i.e., the 25^{th} and 26^{th} positions, thereby leaving out the semiconductor wafers W remaining at the 27^{th} to 32^{nd} positions as shown in FIG. 8B. And then, The CPU 106 allows the operator to perform the manual withdrawal process on the remaining semiconductor wafers W (Step S10), and terminates this process. As such, the process corresponding to abnormalities can be actually and surely performed.

In contrast, in some embodiments, without performing Steps S7 to S9, the automatic withdrawal process may be performed on the semiconductor wafers W having no detected abnormalities (Step S5), and subsequently, if it is determined that some of the semiconductor wafers W remain in the wafer boat 41 (Yes at Step S6), abnormality data may be displayed on the display screen of the manipulation panel 121 (Step S10). In this case, the process corresponding to abnormalities can be actually and surely performed as well.

In the above illustrative embodiments, the skip positions are determined to be in the range of ±1 of the abnormality-detected positions, regardless of the type of abnormality for the abnormality-detected semiconductor wafer W. However, in some embodiments, it may be possible to change a setting of the skip position depending on the type of abnormality so as to determine the skip positions to be in the range of ±2 of the abnormality-detected positions when the type of abnormality is a wafer inclination, for example.

Also, in the aforementioned embodiments, the object to be processed is described as the semiconductor wafer W, but, in some embodiments, it may be a substrate such as, for example, a flat panel display (FPD) substrate, a glass substrate, a plasma display panel (PDP) substrate, and the like.

In the aforementioned embodiments, the control unit 100 may be realized through a general purpose computer without depending on a dedicated system. For example, the control unit 100 may be implemented to perform the foregoing process by installing programs, which are stored on a storage medium (e.g., a flexible disk, a CD-ROM, and the like) for performing the foregoing process, on a general purpose computer.

A medium for providing these programs may be implemented through various kinds of communication medium, networks or systems. In some embodiments, besides the storage medium as described above, the programs may be provided through, for example, communication lines, communication networks, communication systems, or the like. In this case, the programs may be put up on, e.g., a bulletin board system (BBS) of a communication network to be provided through the network via carriers. Thereafter, similar to other application programs, by triggering and executing the thus-provided programs, the foregoing process may be performed under the control of an operating system (OS).

Some embodiments may be achieved by providing a computer (e.g., a controller) with a storage medium storing program codes of software realizing the operations of the present embodiment and allowing a CPU to read and execute the program codes stored in the storage medium.

In such a case, the codes themselves read from the storage medium realizes the functions of the aforementioned embodiment, and thus the present invention includes the program codes and the storage medium storing the program codes

The storage medium for providing the program codes may be, e.g., a RAM, an NV-RAM, a floppy disk, a hard disk, a magneto-optical disk, an optical disk such as CD-ROM, CD-R, CD-RW, and DVD (DVD-ROM, DVD-RAM, DVD-RW, and DVD-RW), a magnetic tape, a nonvolatile memory card, or other types of ROM capable of storing the program codes. The program codes may be provided to the computer by being downloaded from another computer or a database, which is not shown, connected to the Internet, a commercial use network, a local area network, or the like.

The operations of the aforementioned embodiment can be realized by executing the program codes read by the computer or by the actual processing partially or wholly executed by an OS operated on the CPU according to the instructions of the program codes.

In addition, the operations may also be realized by the actual processing partially or wholly executed by a CPU or the like in a built-in function extension board or an external function extension unit of a computer according to the instructions of program codes read from a storage medium after the program codes are inputted into a memory in the built-in function extension board or the external function extension unit. The program codes may be object codes, program codes executed by an interpreter, script data provided to an operating system, or the like.

While certain embodiments have been described, these embodiments have been presented by way of example only, and are not intended to limit the scope of the inventions. Indeed, the novel embodiments herein may be embodied in a variety of other forms. Furthermore, various omissions, substitutions and changes in the form of the embodiments described herein may be made without departing from the spirit of the inventions. The accompanying claims and their equivalents are intended to cover such forms or modifications which would fall within the scope and spirit of the inventions.

1. A method of conveying objects to be processed, the method comprising:
determining whether abnormalities on the objects accommodated in a processing apparatus are detected based on data from sensors disposed on the processing apparatus;
identifying accommodation positions of the objects determined to have the detected abnormalities, and types of the detected abnormalities;
deciding skip positions based on the identified accommodation positions and the identified types of the detected abnormalities; and
skipping a conveyance of the objects accommodated at the decided skip positions and performing an automatic conveyance on the objects having no detected abnormalities.

2. The method of claim 1, further comprising,
identifying automatic conveyable objects among the objects determined to have the detected abnormalities; and
performing the automatic conveyance on the identified automatic conveyable objects.

3. The method of claim 2, wherein identifying automatic conveyable objects is performed based on the types of the detected abnormalities for the objects determined to have the detected abnormalities.

4. The method of claim 2, wherein identifying automatic conveyable objects further comprises:
displaying the decided skip positions;
receiving data in association with an alternation of the decided skip positions being displayed; and
identifying objects to be conveyed automatically based on the received data in association with the alternation of the decided skip positions.

5. The method of claim 2, further comprising, after said performing the automatic conveyance, performing a manual conveyance on the objects remaining in the processing apparatus.

6. An apparatus of conveying objects to be processed, the apparatus comprising:
an abnormality determination unit configured to determine whether abnormalities on the objects accommodated in a processing apparatus are detected based on data from sensors disposed on the processing apparatus;
an abnormality identification unit configured to identify accommodation positions of the objects determined to have the detected abnormalities, and types of the detected abnormalities;
a skip position decision unit configured to decide skip positions based on the identified accommodation positions and the identified types of the detected abnormalities; and
a conveying unit configured to skip a conveyance of the objects accommodated at the decided skip positions and configured to perform an automatic conveyance on the objects having no detected abnormalities.

7. A computer-readable storage medium storing instructions that, when executed by a computer, cause the computer to perform the operations of:
determining whether abnormalities on the objects accommodated in a processing apparatus are detected based on data from sensors disposed on the processing apparatus;
identifying accommodation positions of the objects determined to have the detected abnormalities, and types of the detected abnormalities;
deciding skip positions based on the identified accommodation positions and the identified types of the detected abnormalities; and
skipping a conveyance of the objects accommodated at the decided skip positions and performing an automatic conveyance on the objects having no detected abnormalities.
